(19) United States
(12) Patent Application Publication
(10) Pub. No.: US 2002/0166607 A1
(43) Pub. Date: Nov. 14, 2002

(54) Process and device for low-pressure carbonitriding of steel parts

(76) Inventors: Herwig Altena, Wien (AU); Franz Schrank, Munchendorf (AU)

Correspondence Address: William B. Kircher, SHOOK, HARDY & BACON L.L.P., 1200 Main Street, Kansas City, MO, 64105, US

(21) Appl. No.: 10/114,803

(22) Filed: Apr. 2, 2002

(30) Foreign Application Priority Data
Apr. 4, 2001 (DE) 101 18 494.8-45

(51) Int. Cl. C21D 1/48; C23C 16/00; C23C 8/34

(52) U.S. Cl. 148/218; 118/724; 118/697; 148/318

(57) ABSTRACT

A process for low-pressure carbonitriding of steel parts is disclosed according to which the parts are carburized at low pressure between roughly 780° C. and 1050° C., utilizing a carbon releasing gas at a pressure of less than 500 mbars and are subsequently nitrided utilizing a nitrogen releasing gas comprising NH₃. The nitrogen releasing gas is fed into the treating chamber at the end of the carburization phase at a temperature range of roughly 780° C. to 950° C., starting from a low pressure and ending at a pressure of less than 1000 mbars, for nitriding the parts.

### BACKGROUND OF THE INVENTION

The invention relates to a process for low-pressure carbonitriding of steel parts, wherein the parts are carburized in a temperature range of roughly 780° C. to 1050° C. with a carbon releasing gas at a pressure below 500 mbars and are subsequently nitrided with a nitrogen releasing gas.

The invention further relates to a device for the treatment of steel parts that allows such a treatment, the device comprising at least one treating chamber that can be coupled to a vacuum pump and comprises at least one inlet for a carbon releasing gas and for a nitrogen releasing gas, further comprising a heating device for heating the at least one heating chamber, and further comprising a controller for controlling the temperature and the atmosphere within the at least one treating chamber.

Such a process and such a device are known from DE 199 09 694 A1.

Accordingly, a process for carbonitriding at low pressure is known, according to which a low-pressure carburizing is performed and subsequently a nitriding is performed by utilizing molecular nitrogen or ammonia as a releasing gas at a higher pressure of up to several bars. Thus, the known process is a combination of a low-pressure carburizing with a subsequent nitriding at elevated pressure.

However, how the process shall be performed in detail to yield good treatment results, is not disclosed at all.

Apart from the afore-mentioned publication which does not teach the person skilled in the art how such a carbonitriding process can be performed in practical operation, a low-pressure carbonitriding has not been regarded as possible without a plasma activation to yield sufficient nitrogen contents and carbon contents in the peripheral zone of the treated parts. The reason is seen in the so-called Sievert principle which teaches that the nitrogen solubility in the workpiece decreases with decreasing nitrogen partial pressure within the atmosphere, thus nitrogen diffuses out of the workpiece.

The solution taught by DE 199 09 694 A1, to perform the nitriding at elevated pressure, requires a complicated facility technique of a heating chamber designed as a pressurized container, as well as a considerable gas consumption for filling same.

### SUMMARY OF THE INVENTION

Therefore, it is a first object of the invention to provide a process for carbonitriding of steel parts that allows to carburize and to nitride the parts in the peripheral zone at low pressure up to the desired values.

It is a second object of the invention to provide a process for carbonitriding of steel parts which is simple and cost-effective.

It is a third object of the invention to provide a process for carbonitriding of steel parts which allows to reach a sufficient hardening depth in a subsequent hardening process.

It is a forth object of the invention to provide a process for carbonitriding of steel parts which reduces consumption of gases for carburizing and nitriding.

It is a fifth object of the invention to provide a process for carbonitriding of steel parts which allows for a fast treatment.

It is a sixth object of the the invention to provide a device for carbonitriding of steel parts suitable for carrying out the process according to the invention in an automated way.

These and other objects of the invention are achieved with a process as mentioned at the outset in which a nitriding step is begun at the end of the carburizing step or after cooling to a temperature region of roughly 780° C. to 950° C. while introducing a nitrogen releasing gas containing ammonia, starting at a low pressure up to a pressure of less than 1000 mbars.

Thus, the invention is performed completely.

It has been found that, when introducing a nitrogen releasing gas that at least comprises ammonia or consists mainly of ammonia, at a low pressure into the treating chamber, good treatment results can be reached, when the nitrogen releasing gas thereafter increases in pressure up to a partial pressure of less than 1000 mbars in a temperature range of roughly 780° C. to roughly 950° C.

According to a preferred development of the invention, herein the carburizing is performed at roughly 850° C. to roughly 1000° C., preferably at roughly 850° C. to roughly 950° C., while preferably a pressure of less than 200 mbars, preferably of less than 50 mbars, is maintained.

According to a preferred development of the invention, herein the carburizing step may comprise a plurality of gassing cycles during which the carbon releasing gas is introduced into the at least one treating chamber, while utilizing a plurality of diffusion cycles during which no carbon releasing gas is introduced.

Herein, preferably, propane, acetylene or ethylene are utilized as a carbon releasing gas.

According to another preferred embodiment of the invention, the temperature is lowered to roughly 780° C. to 900° C., preferably to roughly 830° C. to 870° C. before or during nitriding.

For treating the steel Ck45 and the steel 16MnCr5, it has been found advantageous when the carburizing is performed in a temperature range of roughly 850° C. to 950° C. while utilizing a plurality of gassing cycles at a partial pressure of less than 50 mbars for a total treatment time of 10 to 90 min, followed by diffusion cycles at partial pressure, the last gassing cycle being followed by a long diffusion cycle of at least 5 min at a lower pressure of less than 10 mbars.

When performing such a process route, both steels mentioned before and steels with similar features can be sufficiently carburized in the peripheral zones.

Nitriding is preferably performed in a temperature range of roughly 820° C. to 950° C. Depending on the kind of the starting material utilized, in particular depending on its affinity to nitrogen, which is influenced by the alloying elements, depending on the required hardening depths and the temperature utilized, the treatment time is adjusted accordingly. Herein in most cases a treatment time of 15 to 60 min yields good results.

According to an advantageous improvement of the invention, the carburizing phase is started already during the last diffusion cycle by introducing nitrogen releasing gas into the at least one treating chamber, before the cooling to the temperature of the nitriding phase is started.

In this way, a particularly time-saving and thus cost-saving treatment of the parts can be reached.

Preferably, the nitrogen releasing gas is continuously fed during the nitriding phase, starting from a partial pressure of less than 500 mbars, preferably of less than 50 mbars, until a maximum pressure of less than 1000 mbars is reached.

Herein the nitrogen releasing gas can be fed continuously during the whole nitriding phase, or the pressure, after having reached the maximum pressure, can be kept constant.

It has been found that in particular when the pressure is continuously increased during the whole nitriding phase by continuously feeding gas into the treating chamber, which is closed apart from that, nitrogen contents of roughly 0.2 to 0.4 wt.-% can be reached in the peripheral zones.

However, a suitable treatment is also possible, when the pressure after having reached the maximum pressure of less than 1000 mbars, is kept constant. Preferably, a gas consisting largely of ammonia, is utilized as a nitrogen releasing gas. Also some molecular nitrogen may be included at a low partial pressure.

The nitriding can advantageously be performed in the same treating chamber as the carburization.

However, in larger systems also different treating chambers can be utilized for nitriding and for carburizing.

After completion of the nitriding, the parts are chilled, preferably, which can be performed at high pressure by gas chilling.

Additionally, it is preferred to utilize a separate chilling chamber. Thereby, extremely high chilling rates can be reached by utilizing a cold chilling chamber, which is particularly advantageous for low-alloyed and non-alloyed carbon steels which are preferably used for carbonitriding processes.

In a preferred improvement of the process of the invention, a partial nitriding (pre-nitriding) utilizing a nitrogen releasing gas containing ammonia is performed before carburizing.

For instance, this can be performed during the first holding phase in the temperature range of roughly 780 to 1050° C., preferably at a partial pressure of less than 1000 mbars, by feeding nitrogen releasing gas for a certain time interval (e.g. 10 min), for instance at 3 m³/h, starting from a low pressure of roughly 50 mbars or lower.

It has been found that such a pre-nitriding results in a nitrogen enrichment in the peripheral zone after a short time. During the subsequent carburizing, this nitrogen diffuses partially into the material, however, partially diffuses out of the material, due to the low treatment pressure (partial pressure). However, the nitrogen concentration remaining in the material is sufficient to enhance carbon enrichment during the subsequent carburization and to increase the diffusion rate. Thus, in shorter time larger carburization depths can be reached. Thus, the process route can be further enhanced.

The carburization is preferably controlled to yield a carbon content of roughly 0.5 to 1.0 wt.-%, more preferably of roughly 0.7 to 0.9 wt.-%, in the layers close to the surface.

Thus, the forming of residual austenite can be prevented during nitrogen incorporation.

The object of the invention is solved with respect to the device by utilizing a device as mentioned at the outset and by designing the controller such that for a carburization at a temperature of roughly 780° C. to 1050° C., a carbon releasing gas is introduced into the treating chamber up to a pressure of less than 500 mbars, and that a nitrogen releasing gas containing ammonia is introduced into the treating chamber up to a partial pressure of less than 1000 mbars for a subsequent nitriding at a temperature of 780° C. to 950° C.

This device preferably also comprises means for high pressure chilling of the parts.

Such a device is suitable for performing the process according to the invention, wherein temperature and atmosphere can be controlled fully automatically by a computer program, thus ensuring a high reproducibility of treatment.

Further advantages can be reached by feeding gas containing ammonia only up to a partial pressure which is below the atmospheric pressure.

Thereby, the safety measures otherwise to be taken when utilizing ammonia are considerably simplified which facilitates a cost-saving design of the device and a cost-saving processing. Also the consumption of process gas can be lowered to roughly 5 to 30% of the volumes necessary in the prior art. Also a costly design of the heating chamber as a pressurized container can be avoided.

Needless to say, the features of the invention mentioned before and to be disclosed hereinafter cannot only be utilized in the given combination but also in other combinations or on their own, without extending the scope of the invention.

### BRIEF DESCRIPTION OF THE DRAWINGS

Specific embodiments of the invention are shown in the drawing and explained in the subsequent description, in which:

FIG. 1 shows a schematic representation of a device suitable for performing the process of the invention;

FIG. 2a), b)shows a temperature profile and pressure profile for performing the inventive process, in simplified representation;

FIG. 3 shows a schematic representation of a multichamber treatment device for performing the process of the invention; and

FIG. 4a), b)shows a temperature profile and pressure profile of a process according to the invention slightly different from the process shown in FIG. 2a), b), in simplified representation.

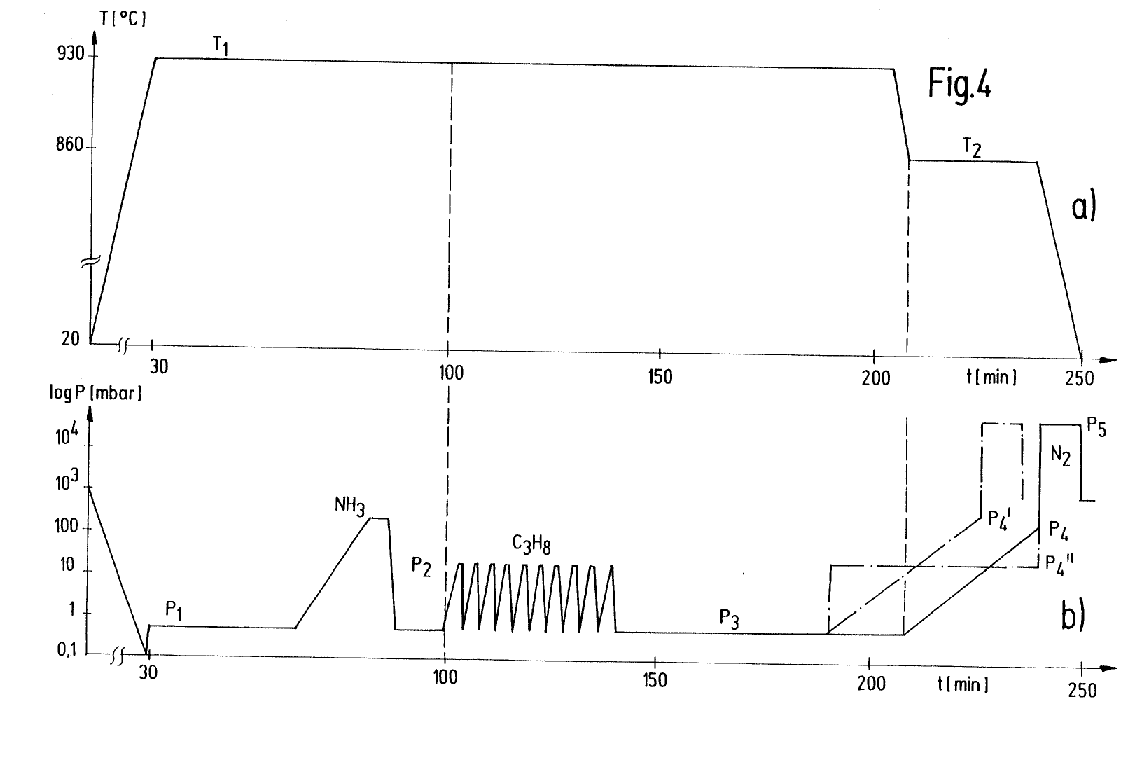

### DETAILED DESCRIPTION OF THE PREFERRED EMBODIMENTS

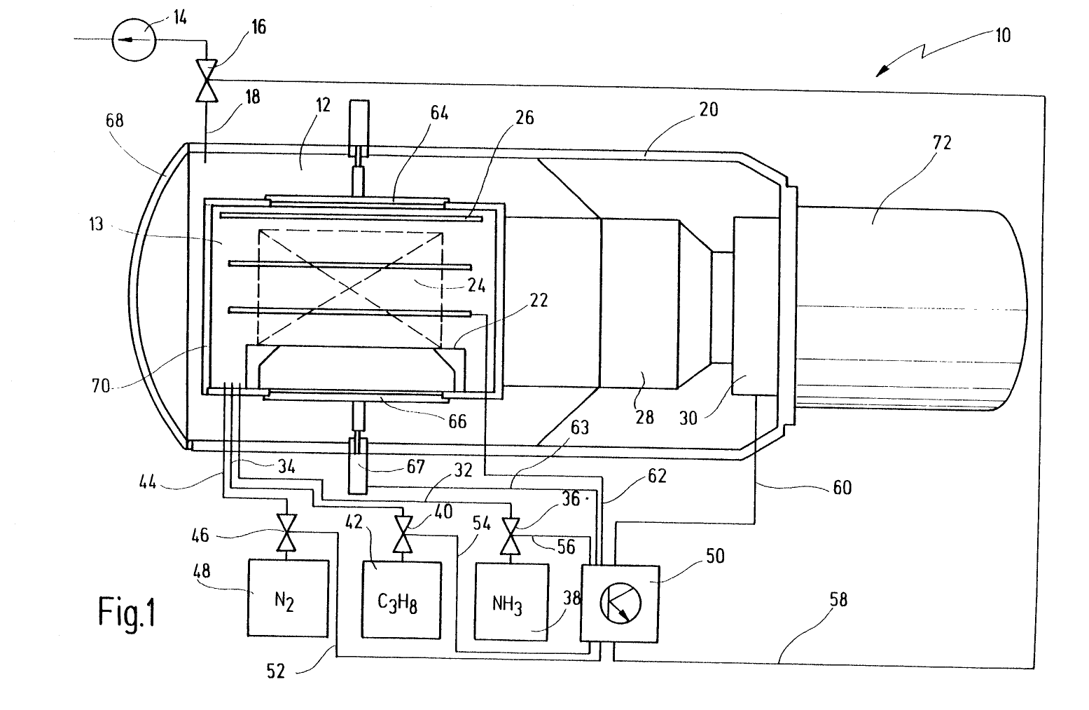

In FIG. 1, a device for performing a low-pressure carbonitriding treatment of steel parts 24 is depicted schematically and denoted with numeral 10 in total. The process 10 comprises a treating chamber 12, which is enclosed by a housing 20 in a gas-tight manner and which may be enhoused by a cooling system (e.g. water cooling) and which may be closed at its front side by a cover 68 in a gas-tight manner. Within the treating chamber 12 a heating chamber 13 is provided which may be closed at its front side facing the cover 68 by a door 70, while its top and bottom sides are closed by displaceable doors 64, 66.

A part holder 22 in which parts 24 can be held, can be introduced into the heating chamber 13. Within the heating chamber, a plurality of heating elements 26 is provided. Laterally adjacent the heating chamber 13, a fan 30 driven by a motor 72 and a coolant exchanger 28 may be arranged therebefore, allowing a gas chilling under high pressure.

The device 10 further comprises a vacuum pump 14 which may be coupled to the treating chamber 12 via a valve 16 and a pipe 18 for evacuating same.

In addition, the treating chamber 12 comprises several gas inlets to allow feeding of several gases, in particular nitrogen, propane, acetylene, ethylene, or ammonia in a suitable way. To this end, a pressurized nitrogen container 48 communicates via a valve 46 and via a pressure reducer (not shown) with an inlet 44 leading into the treating chamber 12.

In addition, a pressurized container 42 for holding propane also communicates via a pressure reducer (not shown) and a valve 40 with an inlet 34 leading into the treating chamber 12. Finally, a pressurized container 38 for holding ammonia gas also communicates via a pressure reducer (not shown) and a valve 36 with an inlet 32 leading into the treating chamber 12.

In addition, the device 10 comprises a central controller 50, preferably designed as a programmable controller that is coupled by a variety of control lines 52, 54, 56, 58, 60, 62 with respective valves 46, 40, 36 and with the pressure reducers for the containers 48, 42, 38 coupled therewith, as well as with valve 16 and vacuum pump 14, also with heating elements 26, for controlling temperature, pressure and gas atmosphere composition within the treating chamber 12 in a selective way. In addition, the controller is coupled with an activation mechanism 67 for the top and bottom doors 64, 66 of heating chamber 13 and with fan 30 via lines 63, 60, to allow a high pressure gas chilling.

For performing a gas chilling, upper and lower doors 64, 66 of heating chamber 13 are opened, cooling gas is introduced into treating chamber 12 and circulated via the heat exchanger 28 by means of the fan 30.

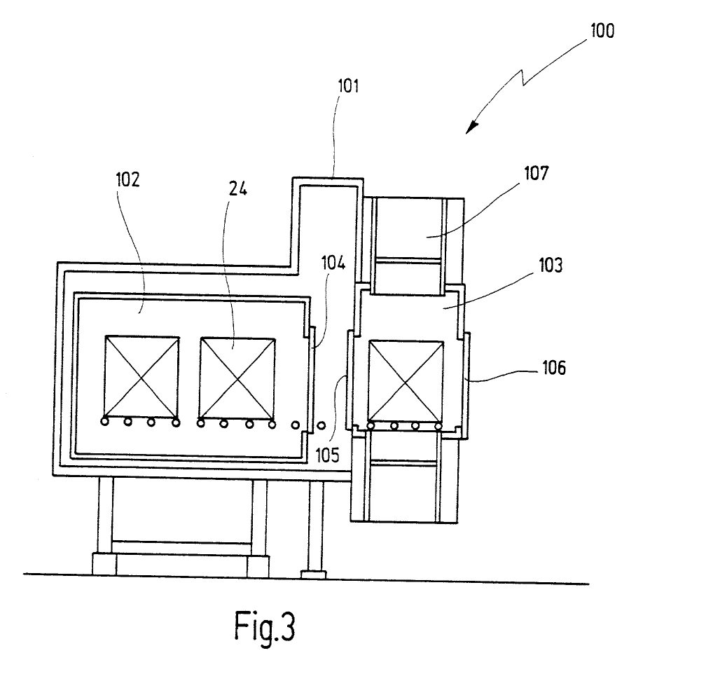

A different embodiment of a device for performing a low pressure carbonitriding treatment is shown in FIG. 3 very schematically and denoted in total with numeral 100. Herein, the device is designed as a multi-chamber device in which the carbonitriding process can be performed in a treating chamber 102 and the chilling process can be performed in a chilling chamber 103 separated therefrom.

Again, the device 100 is enhoused by a gas-tight housing 101 within which the treating chamber 102 for carbonitriding treatment of parts 24 is located lockable by a door 104. Before that, a chilling chamber 103 is provided which can be closed via doors 105, 106 and which is equipped with a gas chilling device 107, including a fan and a heat exchanger, for chilling of parts.

The additional parts such as gas pipes, control lines, valves, controls, etc. are not shown for the sake of simplicity.

For any particular material of the parts 24 to be treated, having a given geometry and for selected values with respect to the carbon and nitrogen contents in the peripheral zone and also for a particular desired hardening depth, the whole process is preferably performed program-controlled, so that the process can be followed fully automatically, in case the treatment parameters for the particular application have been optimized before.

The treating chamber 12 is sufficiently pressure-resistent, to also allow a high pressure chilling at a gas pressure of 15 bars or more.

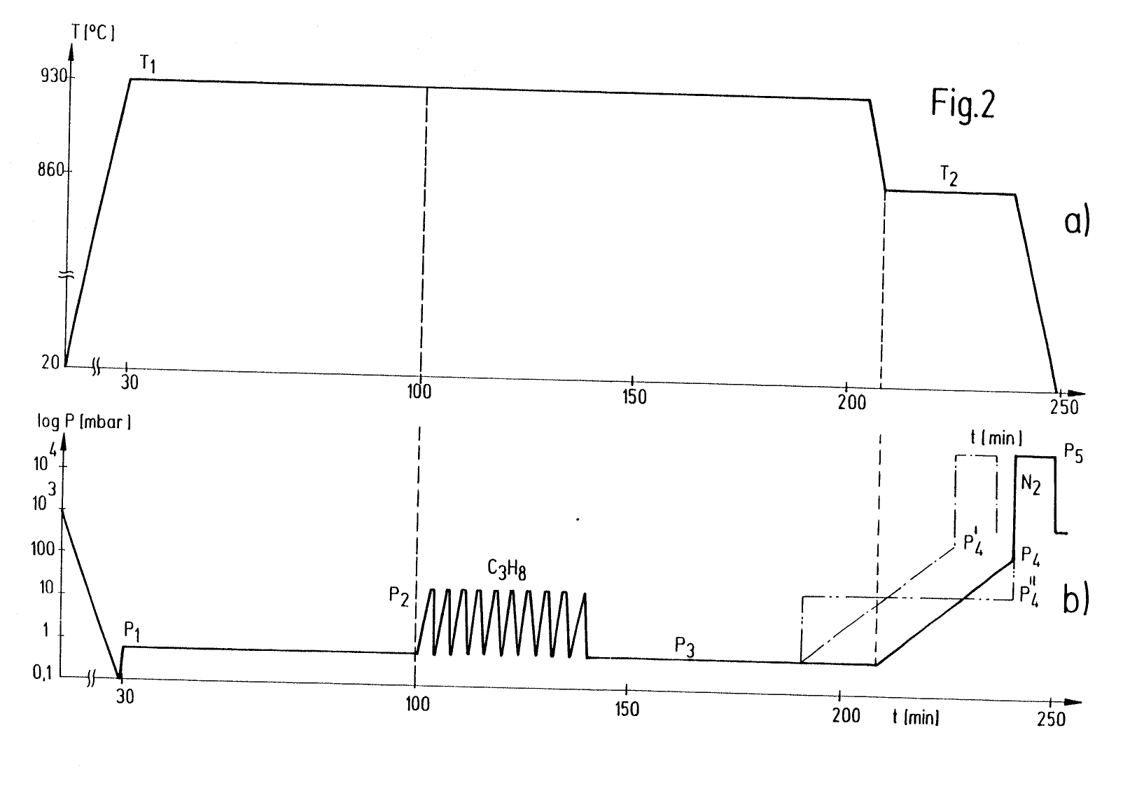

In the following, the treating process which may typically be performed for low-pressure carbonitriding and subsequent hardening by gas chilling is explained with reference to FIGS. 2a) and 2b).

After degreasing of the parts which may be performed by a washing process or merely in a thermal way, the parts are heated to a temperature T₁, at which a carburization is performed. The temperature of carburization may basically lie in the range of 780° C. to 1050° C., preferably in the range of roughly 900° C. to 1000° C., while in the case shown a temperature of 930° C. was selected. The heating to temperature T₁ may, for instance, be performed within 30 min. Simultaneously, the pressure P is lowered as far as possible, starting from atmospheric pressure, to extract residual oxygen, and is thereafter raised to a pressure P₁ which is below 50 mbars, preferably roughly 1.0 or 0.8 mbars. Thereafter, a holding step at constant pressure P₁, and constant temperature T₁, is performed which may last 1 to 2 h, e.g. 1.5 h. While the temperature T₁ is further controlled to be constant, a carburization treatment is subsequently performed, utilizing a sequence of gassing cycles during which carbon releasing gas, e.g. propane, is introduced into the treating chamber 12. Each gassing cycle is preferably followed by a short diffusion time without gas admission, while the last gassing cycle is followed by a longer diffusion time without any gas admission. The number of gassing cycles, the duration of the respective gas feeding, and the gas feed rate depend on the kind of steel utilized and on the carbon concentration desired in the peripheral zone.

For instance, for a steel Ck45 or 16MnCr5, 4 cycles of feeding propane at 20 mbars for 3 min each at a feed rate of 600 l/h can be performed. This can be followed by a diffusion cycle of 1 min each, which may, for instance, be followed by 6 cycles of feeding propane at 20 mbars for 3 min each at 400 l/h, which each are followed by a diffusion cycle of 1 min. The last gas feeding cycle may be followed by a longer diffusion cycle at a partial pressure P₃ which may be equal to partial pressure P₁ and which may take 0.5 to 2 h, e.g. 65 min.

At the end of this diffusion cycle, the temperature T₁ is lowered to a lower temperature T₂ at which nitriding is performed. Nitriding can basically be performed in a temperature range of roughly 780° C. to 950° C. while utilizing a nitrogen releasing gas which comprises ammonia to a large extent. Herein, preferably a temperature range between 800° C. and 900° C. is selected, or roughly 860° C., as shown in the current case.

When reaching temperature T₂, starting with a pressure P₃, nitrogen releasing gas, thus for instance ammonia gas, is fed at 1 m³/h, while vacuum valve 16 is closed. If the treating chamber 12 has, for instance, a volume of 5.3 m³, the pressure raises to pressure P₄ which is roughly 400 mbars in the example shown, during a time of 30 min.

In a variation of the process, it is possible to feed an inert gas, such as N₂, into the treating chamber in the beginning, for instance to flood up to 500 mbars and to start feeding NH₃ only thereafter.

Preferably, thereafter a high-pressure gas chilling utilizing nitrogen is performed. To this end, the pressure may, for example, be raised to 15 bars for a short time, and thereafter a fast cooling down to room temperature may be performed within roughly 5 min, while being assisted by fan 30. Alternatively, the pressure may be lowered by evacuating first, and thereafter a flooding with coolant gas (N₂) may be performed.

Needless to say, the temperature and pressure profiles shown in FIGS. 2a) and b) are simplified, to merely explain the ideal course, while in reality naturally a heating or cooling, respectively, is not performed at constant heating or cooling rates, respectively, and also the pressure variations are usually not linear.

However, the principle can be easily seen from FIGS. 2a) and b).

The best nitriding results in the peripheral zone were reached by continuously feeding ammonia during the total nitriding phase while keeping vacuum valve 16 closed.

When utilizing a flow-through, i.e. a continuous feeding of nitrogen releasing gas, while vacuum valve 16 is open, at a feed rate of 1 m³ NH₃ for 30 min during the temperature holding phase at temperature T₂, also a desired incorporation of nitrogen into the peripheral zone can be reached, while keeping the same remaining parameters. However, larger NH₃-volumes must be fed.

It is contemplated to start with the feeding of ammonia even before the last diffusion cycle has ended, such as shown with the dash-dotted line in FIG. 2b), i.e. still at the carburizing phase, beginning at temperature T₁ and going on continuously, until after completion of the diffusion cycle, the temperature is lowered from T₁ to T₂, the holding temperature for the nitriding phase.

As known in the art, at higher temperature ammonia dissociates faster into N₂ and H₂, whereby nitrogen at the higher temperature cannot be incorporated into the austenite so fast, since the intermediate products NH₂, NH, N and H transform faster to the final products H₂ and N₂. Thus, the nitriding results at lower temperature T₂ are better than at higher temperature T₁. However, by starting earlier with a feeding of NH₃, the necessary total time up to reaching the final nitrogen concentration can be shortened.

In FIG. 2b a feeding through of gas (see double dash-dotted line) is shown as another possibility, this leading to a lower, constant pressure P₄″. However, this does not lead to the same advantageous results like the continuous pressure elevation and constant gas feeding with closed vacuum valve 16.

Also it was found that the capacity of the steel for incorporating nitrogen was influenced by the respective peripheral carbon content. Thus, a nitriding of an Fe-sheet (0.01% C) at 930° C. by feeding NH₃ gas for 10 min led to a nitrogen content of 0.78%. By contrast, a nitriding of an Fe-sheet of 0.76% C only led to a nitrogen content of 0.31%, while keeping the remaining parameters the same. The capacity for incorporating nitrogen further decreases with increasing carbon content up to saturation. To this end, according to the invention the nitriding is performed subsequent to the diffusion phase (or, respectively, during diffusion) while the peripheral carbon content has been lowered already, but is not performed already during carburization cycling.

A further advantageous process design can be reached by performing a nitriding at the beginning of the process (pre-nitriding), i.e. after having reached the treatment temperatures, but before beginning with the low-pressure carburization. Thereby, within a short time of e.g. 10 min, a considerable nitrogen enrichment can be reached within the peripheral zone. During the subsequent carburization process, this nitrogen partially diffuses into the material, however also it partially effuses due to the low partial pressure. However, the residual nitrogen content within the material is sufficient to enhance the carbon incorporation as well as the diffusion rate of carbon into the material. Thus, in shorter times larger carburization depths can be reached.

### EXAMPLE 1

In a treating chamber 12 having a volume of roughly 5.3 m³, approximately 50 rods having a diameter of 20 mm and a length of 500 mm from Ck15 (ballast) and 2 polished specimen from Ck45 and two polished specimen from 16MnCr5, were treated.

Herein, at the beginning for 30 min a heating to a temperature T₁ of 930° C. was performed while evacuating as far as possible. Subsequently, a holding step at 930° C. and at a partial pressure of 0.8 mbars was performed for 70 min. Thereafter, a carburization phase for a total time of 104 min was performed, including 4 cycles of 3 min each gas feeding (propane) at 600 l/h at 20 mbars, each followed by a diffusion cycle of 1 min. This was followed by 6 cycles of a gas feeding (propane) at 20 mbars at 400 l/h for 3 min each, each followed by a diffusion cycle of 1 min each. The last gassing cycle was followed by a diffusion cycle also at temperature T₁ (930° C.) for 65 min at a partial pressure of 0.8 mbars. Thereafter, a cooling to the temperature T₂ of 860° C. was performed, this followed by a nitriding phase at T₂ for 30 min, feeding 1 m³/h NH₃, while vacuum valve 16 was closed.

This was followed by a gas chilling with N₂ at 15 bars.

The samples thus produced were analyzed for their carbon contents and their nitrogen contents in their peripheral zones, utilizing GDOS analyses. Within steel 16MnCr5, a content of roughly 0.75% C and of roughly 0.5% N was found up to a depth of roughly 0.3 mm. Within Ck45, a carbon content of 0.77% C and a nitrogen content of roughly 0.3% N was found in the peripheral zone, up to a depth of roughly 0.4 mm. This yielded a surface hardness of roughly 600 HV with Ck45.

It is believed that the enhanced incorporation of nitrogen into 16MnCr5 (roughly 0.5% N) in comparison to 0.3% N into Ck45 is due to the higher affinity of the alloying elements to nitrogen and to the formation of finely dispursed Cr-nitrides.

Common peripheral nitrogen contents of 0.25 to 0.4% can preferably be reached by feeding of gas, while raising pressure at the same time. It was shown by comparison tests that, when using gas-throughput, an equilibrium concentration depending from the feed rate of NH₃ and from the temperature is reached, which may be, in part, particularly lower when compared with gas feeding, while raising pressure.

A diffusion of nitrogen out off the peripheral zone was not found, in spite of evacuating (and transporting the batch within the evacuated device according to FIG. 3).

However, using only N₂ at 1 bar did not yield the desired nitrogen content within the material.

### EXAMPLE 2

While keeping the remaining parameters the same like in Example 1, specimen from 16MnCr5 were heated first to 930° C. while largely evacuating, and were thereafter kept at 930° C. and a partial pressure of 0.8 mbars for 70 min. Departing from Example 1 during the holding phase at 930° C. before beginning with the low-pressure carburization, a short nitriding (prenitriding) was performed, by feeding NH₃ at 3 m³/h for 10 min. Thereafter, the process was continued as described with reference to Example 1.

The samples produced in this way were again examined for their carbon contents. Higher carbon contents were found which increased in the peripheral zone to roughly 0.85% C, having a carburization depth roughly 0.1 mm deeper when compared with Example 1.

In this way, larger carburization depths can be reached in equal times, or equal carburization depths can be reached within shorter treatment times.

What is claimed is:

1. A process for carbonitriding of steel parts comprising the steps of:
introducing the steel parts into a treating chamber;
evacuating the treating chamber to less than 500 mbars and heating the treating chamber to a temperature in the range of 780° C. to 1050° C.;
feeding a carbon releasing gas into the treating chamber and carburizing the parts at a pressure of less than 500 mbars;
feeding a nitrogen releasing gas comprising ammonia gas into the treating chamber at a partial pressure of less than 1000 mbars; and
nitriding the parts at a temperature in the range of 780° C. to 950° C.

2. The process of claim 1, wherein the step of carburizing is performed at a temperature in the range of 850° C. to 1000° C.

3. The process of claim 1, wherein the step of carburizing is performed at a temperature in the range of 850° C. to 950° C.

4. The process of claim 1, wherein the step of carburizing is performed at a pressure in the range of less than 200 mbars.

5. The process of claim 1, wherein the step of carburizing is performed at a pressure in the range of less than 50 mbars.

6. The process of claim 1, wherein the step of carburizing comprises a cycling of carbon releasing gas between a maximum pressure of less than 500 mbars and a minimum pressure lower than the maximum pressure.

7. The process of claim 1, wherein the step of carburizing comprises a cycling of carbon releasing gas between a maximum pressure of less than 200 mbars and a minimum pressure lower than the maximum pressure.

8. The process of claim 1, wherein the step of carburizing comprises a cycling of carbon releasing gas between a maximum pressure of less than 50 mbars and a minimum pressure lower than the maximum pressure.

9. The process of claim 1, wherein the carbon releasing gas comprises at least one gas of the group formed by propane, acetylene and ethylene.

10. The process of claim 1, wherein the temperature during the step of nitriding is lowered to the range of 830° C. to 870° C.

11. The process of claim 8, wherein a last cycle of feeding carbon releasing gas is followed by a diffusion step at a pressure lower than 10 mbars.

12. The process of claim 1, wherein said nitriding step is performed at a temperature in the range of 820° C. to 950° C. for 10 to 90 minutes.

13. The process of claim 6, wherein the step of feeding nitrogen releasing gas into the treating chamber is begun before the step of carburizing has been completed.

14. The process of claim 6, wherein the step of feeding nitrogen releasing gas into the treating chamber is begun after the last cycle of feeding carbon releasing gas has ended.

15. The process of claim 1, wherein the step of feeding nitrogen releasing gas into the treating chamber comprises a continuous feeding of nitrogen releasing gas into the treating chamber until a maximum partial pressure of less than 1000 mbars is reached.

16. The process of claim 1, wherein the parts are gas chilled after completion of the nitriding step.

17. The process of claim 1, wherein the steps of carburizing and nitriding are performed in the same treating chamber.

18. The process of claim 1, wherein the steps of carburizing and nitriding are performed in the different treating chambers.

19. A process for carbonitriding of steel parts comprising the steps of:
introducing the steel parts into a treating chamber;
evacuating the treating chamber to less than 500 mbars and heating the treating chamber to a temperature in the range of 780° C. to 1050° C.;
feeding a nitrogen releasing gas comprising ammonia gas into the treating chamber and partially nitriding the parts at a partial pressure of less than 1000 mbars;
evacuating the treating chamber to a pressure of less than 500 mbars;
feeding a carbon releasing gas into the treating chamber and carburizing the parts at a pressure of less than 500 mbars at a temperature in the range of 780° C. to 1050° C.;
feeding a nitrogen releasing gas comprising ammonia gas into the treating chamber at a partial pressure of less than 1000 mbars; and
nitriding the parts at a temperature in the range of 780° C. to 950° C.

20. The process of claim 19, wherein the step of carburizing is performed at a temperature in the range of 850° C. to 1000° C.

21. The process of claim 19, wherein the step of carburizing is performed at a temperature in the range of 850° C. to 950° C.

22. The process of claim 19, wherein the step of carburizing is performed at a pressure in the range of less than 200 mbars.

23. The process of claim 19, wherein the step of carburizing is performed at a pressure in the range of less than 50 mbars.

24. The process of claim 19, wherein the step of carburizing comprises a cycling of carbon releasing gas between a maximum pressure of less than 500 mbars and a minimum pressure lower than the maximum pressure.

25. The process of claim 19, wherein the step of carburizing comprises a cycling of carbon releasing gas between a maximum pressure of less than 200 mbars and a minimum pressure lower than the maximum pressure.

26. The process of claim 19, wherein the step of carburizing comprises a cycling of carbon releasing gas between a maximum pressure of less than 50 mbars and a minimum pressure lower than the maximum pressure.

27. The process of claim 19, wherein the carbon releasing gas comprises at least one gas of the group formed by propane, acetylene and ethylene.

28. The process of claim 19, wherein the temperature during the step of nitriding is lowered to the range of 830° C. to 870° C.

29. The process of claim 26, wherein the last cycle of carbon releasing gas is followed by a diffusion step at a pressure lower than 10 mbars.

30. The process of claim 19, wherein said nitriding step is performed at a temperature in the range of 820° C. to 950° C. for 10 to 90 minutes.

31. The process of claim 26, wherein the step of feeding nitrogen releasing gas into the treating chamber is begun before the step of carburizing has been completed.

32. The process of claim 26, wherein the step of feeding nitrogen releasing gas into the treating chamber is begun after the last cycle of introducing carbon releasing gas has ended.

33. The process of claim 19, wherein the step of feeding nitrogen releasing gas into the treating chamber comprises a continuous feeding of nitrogen releasing gas into the treating chamber until a maximum partial pressure of less than 1000 mbars is reached.

34. The process of claim 19, wherein the initial step of feeding nitrogen releasing gas into the treating chamber for partially nitriding the parts comprises a continuous feeding of nitrogen releasing gas into the treating chamber until a maximum partial pressure of less than 500 mbars is reached.

35. The process of claim 19, wherein the parts are gas chilled after completion of the nitriding step.

36. The process of claim 1, wherein the nitrogen releasing gas comprises mainly ammonia gas.

37. A steel part manufactured by the process of claim 1.

38. A steel part manufactured by the process of claim 19.

39. A device for treating steel parts comprising:
at least one treating chamber for receiving parts;
a vacuum pump for evacuating the treating chamber;
a gas inlet for feeding gas into the treating chamber;
valve means coupled to said gas inlet and at least one carbon releasing gas source and at least one nitrogen releasing gas source comprising ammonia gas for controlling the feeding of carbon releasing and nitrogen releasing gases into the treating chamber;
a heater for heating said treating chamber; and a programmable controller coupled to said heater, said vacuum pump and said valve means for controlling the heating and evacuating of said treating chamber and the introduction of carbon releasing gas and nitrogen releasing gas into the treating chamber;
wherein said controller is programmed for
evacuating the treating chamber to less than 500 mbars and heating the treating chamber to a temperature in the range of 780° C. to 1050° C.;
feeding carbon releasing gas from said carbon releasing gas source into the treating chamber and carburizing the parts at a pressure of less than 500 mbars;
feeding nitrogen releasing gas from said nitrogen releasing gas source into the treating chamber at a partial pressure of less than 1000 mbars; and
nitriding the parts at a temperature in the range of 780° C. to 950° C.
